(19) United States
(12) Patent Application Publication
(10) Pub. No.: US 2009/0108877 A1
(43) Pub. Date: Apr. 30, 2009

(54) Logic Gate and Semiconductor Integrated Circuit Device Using the Logic Gate

(76) Inventors: Osamu Kawagoe, Tokyo (JP); Akira Sato, Tokyo (JP)

Correspondence Address: IPUSA, P.L.L.C, 1054 31ST STREET, N.W., Suite 400, Washington, DC, 20007, US

(21) Appl. No.: 12/255,697

(22) Filed: Oct. 22, 2008

(30) Foreign Application Priority Data
Oct. 25, 2007 (JP) 2007-278065

(51) Int. Cl. H03K 19/20

(52) U.S. Cl. 326/121

(57) ABSTRACT

A disclosed logic gate including a CMOS circuit having a p-channel MOS transistor and an n-channel MOS transistor and also includes a resistance device connected in series with a source or a drain of at least one of the p-channel MOS transistor and the n-channel MOS transistor, a switching device connected in parallel with the resistance device and configured to switch on and off, and a switching control circuit configured to control the switching on and off of the switching device according to an output signal output from the CMOS circuit.

### BACKGROUND OF THE INVENTION

1. Field of the Invention

The present invention generally relates to a logic gate and a semiconductor integrated circuit device using the logic gate, for examples a logic gate including a CMOS circuit or a semiconductor integrated circuit device using the logic gate.

2. Description of the Related Art

A complementary metal oxide semiconductor (CMOS) inverter circuit, which includes an inverter having logic circuit devices formed of pairs of complementary p-channel MOS transistors and n-channel MOS transistors, is known in the related art.

FIG. 8 depicts a CMOS inverter circuit according to a related art example. In FIG. 8, a gate of a p-channel MOS transistor MP50 and a gate of a n-channel MOS transistor MN50 are connected to form a common input part A whereas a drain of the p-channel MOS transistor MP50 and a drain of the n-channel MOS transistor MN50 are connected to form a common output part Y. Further, a source of the p-channel MOS transistor MP50 is connected to a power supply Vdd whereas a source of the n-channel MOS transistor MN50 is connected to ground GND.

In a case where a low (L) level voltage signal is input to the input part A of the CMOS inverter circuit illustrated in FIG. 8, the p-channel MOS transistor MP50 is switched on to cause a power supply voltage VDD to be output. In this case, a high (H) level signal is output from the output part Y. On the other hand, in a case where a high (H) level voltage signal is input to the input part A, the n-channel MOS transistor MN50 is switched on to ground the output part Y. In this case, a low (L) level signal is output from the output part Y. Accordingly, with the CMOS inverter circuit illustrated in FIG. 8, signals input to the CMOS inverter circuit are inverted and output. Thus, the CMOS inverter circuit can function as an inverter device (NOT gate) of a logic circuit.

FIG. 9 illustrates an input/output characteristic showing a relationship of an input voltage and an output voltage of the CMOS inverter circuit illustrated in FIG. 8. In FIG. 9, the horizontal axis is for indicating input voltage Vin [V] input to the input part A and the vertical axis is for indicating output voltage Vout [V] output from the output part Y. As described above, the output voltage Vout output from the output part Y is a high level voltage when the input voltage Vin input to the input part A is a low level. Therefore, although a high level output voltage Vout is output from the output part Y where the input voltage Vin input to the input part A is a low level, the output voltage Vout is switched to a low level when the input voltage Vin surpasses approximately half of the supply voltage Vdd and becomes a high level. That is, the CMOS inverter circuit has a voltage characteristic of switching the output voltage Vout to a low level upon reaching a threshold for switching the output. Thereby, the CMOS inverter circuit functions as an inverter.

One example of the inverter circuit is a hysteresis circuit as shown in Japanese Laid-Open Patent Application No. 54-74353. The hysteresis circuit includes an inverter circuit formed of first CMOS transistors, second CMOS transistors of the same polarity connected in parallel with the first CMOS transistors, a switching part for switching the second CMOS transistors, and fourth CMOS transistors of the same polarity commonly connected in series with the first and second CMOS transistors, wherein the fourth CMOS transistors are switched according to the input level of the inverter circuit.

However, as shown in the input/output voltage characteristic of FIG. 9, the configuration illustrated in FIG. 8 has no hysteresis characteristic and exhibits an input/output characteristic of abruptly switching output voltage at the vicinity of a predetermined threshold. This results in a problem of chattering or the like when the switching occurs. That is, regarding the input/output characteristic of FIG. 9, when the input voltage Vin input to the input part A increases from a low level and reaches a threshold voltage approximately half of the power supply voltage Vdd, the output voltage Vout exhibits a steep switch from a high level to a low level. Likewise, when the input voltage Yin input to the input part A decreases from a high level to a low level and reaches the threshold voltage, the output voltage Vout steeply switches from a low level to a high level. Because this input/output characteristic has no hysteresis, a problem such as chattering tends to occur during the switching and results in malfunction of the logic circuit.

Further, with the above-described configuration of Japanese Laid-Open Patent Application No. 54-74353, all of the circuit devices of the configuration being MOS transistors causes hysteresis having a large voltage width and makes it difficult to obtain a small hysteresis. Further, it is difficult to adjust hysteresis with the above-described configuration of Japanese Laid-Open Patent Application No. 54-74353 since the configuration requires changing the characteristic of its MOS transistors (design change) in order to make a slight adjustment of hysteresis.

### SUMMARY OF THE INVENTION

The present invention provides a logic circuit and a semiconductor integrated circuit apparatus that substantially eliminate one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by a logic circuit and a semiconductor integrated circuit apparatus particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the present invention provides a logic gate including a CMOS circuit having a p-channel MOS transistor and an n-channel MOS transistor, having a resistance device connected in series with a source or a drain of at least one of the p-channel MOS transistor and the n-channel MOS transistor, a switching device connected in parallel with the resistance device and configured to switch the resistance device on and off, and a switching control circuit configured to control the switching on and off of the switching device according to an output signal output from the CMOS circuit.

Furthermore, another embodiment of the present invention provides a semiconductor integrated circuit device including a semiconductor substrate having a logic gate including a CMOS circuit having a p-channel MOS transistor and an h-channel MOS transistor, the logic gate including a resistance device connected in series with a source or a drain of at least one of the p-channel MOS transistor and the n-channel MOS transistor, a switching device connected in parallel with the resistance device and configured to switch the resistance device on and off, and a switching control circuit configured to control the switching on and off of the switching device according to an output signal output from the CMOS circuit; and a package having the semiconductor substrate packaged therein.

Other objects and further features of the present invention will be apparent from the following detailed description when read in conjunction with the accompanying drawings.

### BRIEF DESCRIPTION OF THE DRAWINGS

FIG. 1 is a schematic diagram illustrating a circuit configuration of a CMOS inverter circuit according to a first embodiment of the present invention;

FIG. 2 is a graph illustrating an input/output characteristic of a CMOS inverter circuit according to an embodiment of the present invention;

FIG. 3 is a schematic diagram illustrating a circuit configuration of a CMOS inverter circuit according to a second embodiment of the present invention;

FIG. 4 is a schematic diagram illustrating a circuit configuration of a CMOS inverter circuit according to a third embodiment of the present invention;

FIG. 5 is a schematic diagram illustrating a circuit configuration of a CMOS inverter circuit according to a fourth embodiment of the present invention;

FIG. 6 is a schematic diagram illustrating a circuit configuration of a logic gate according to a fifth embodiment of the present invention;

FIG. 7 is a schematic diagram illustrating a circuit configuration of a logic gate according to a sixth embodiment of the present invention;

FIG. 8 is a diagram illustrating a CMOS inverter circuit according to a related art example;

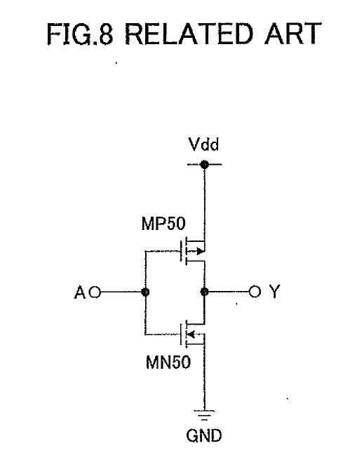

FIG. 9 is a graph showing an input/output characteristic of a CMOS inverter circuit according to a related art example; and

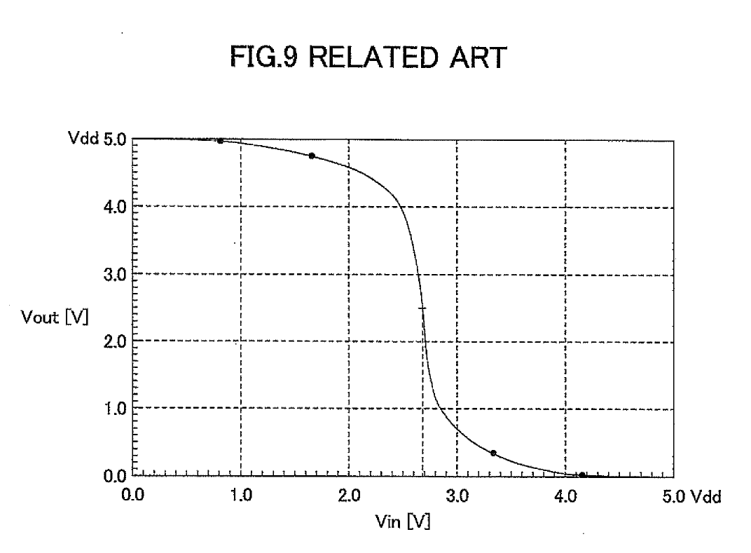

FIG. 10 is a schematic diagram illustrating a semiconductor integrated circuit device having a package for installing a semiconductor substrate therein according to an embodiment of the present invention.

### DESCRIPTION OF THE PREFERRED EMBODIMENTS

In the following, embodiments of the present invention will be described with reference to the accompanying drawings.

### First Embodiment

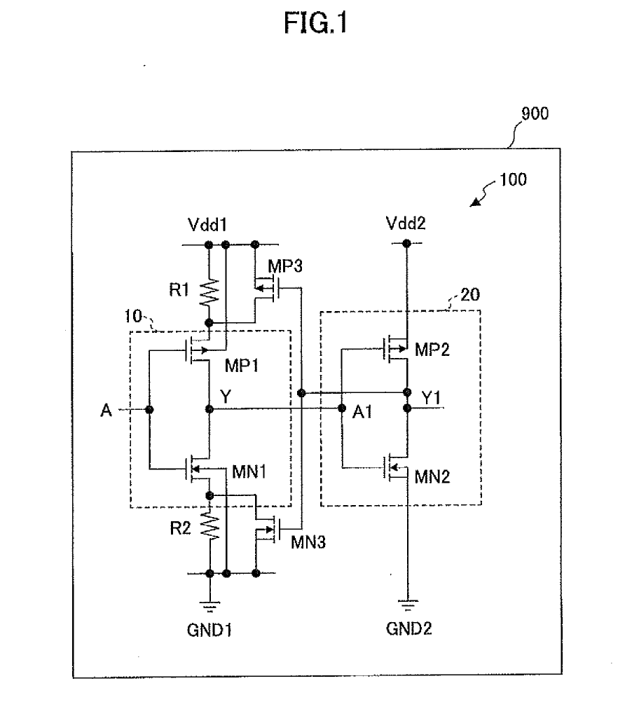

FIG. 1 illustrates a CMOS inverter circuit 100, that is, a circuit configuration of a NOT gate according to the first embodiment of the present invention. In FIG. 1, the CMOS inverter circuit 100 according to the first embodiment has: a first CMOS circuit 10 including a p-channel MOS transistor MP1 and an n-channel MOS transistor MN1; resistors R1, R2 that are connected to the respective sources of the MOS transistors MP1 and MN1; a second CMOS circuit (also referred to as “switching control circuit” described in detail below) 20 including a p-channel MOS transistor MP2 and an n-channel MOS transistor MN2 that is connected to an output part Y of the CMOS circuit 10; a p-channel MOS transistor MP3 connected in parallel with the resistor R1; and an n-channel MOS transistor MN3.

The CMOS circuit 10 including the combination of the p-channel MOS transistor MP1 and the n-channel MOS transistor MN1 is configured as a logic inverter circuit (signal inverting circuit). The CMOS circuit 10 connects the gates of the MOS transistors MP1 and MN1 to provide an input part A of the CMOS inverter circuit 100 and connects the drains of the MOS transistors MP1 and MN1 to provide the output part Y of the CMOS inverter circuit 100. Further, the source of the p-channel MOS transistor MP1 is connected to a power supply Vdd1 via the resistor R1. Further, the back gate of the p-channel MOS transistor MP1 is connected to the power supply Vdd1. On the other hand, the source of the n-channel MOS transistor MN1 is connected to ground GND1 via the resistor R2. Further, the back gate of the n-channel MOS transistor MN1 is directly connected to ground GND1. The CMOS circuit 10 is configured as an inverter that switches on the p-channel MOS transistor MP1 and outputs a high (H) level voltage signal of the power supply Vdd1 from the output part Y in a case where a low (L) level voltage signal is input to the input part A. On the other hand, in a case where an H level voltage signal is input to the input part A, the CMOS circuit 10 switches on the n-channel MOS transistor MN1 and outputs an L level voltage signal of 0 V of ground GND1 from the output part Y. Thus, the CMOS circuit 10 is configured as a logic NOT gate for inverting an input L level signal and outputting an H level signal and inverting an input H level signal and outputting a L level signal.

The resistors R1, R2 are for generating a desired hysteresis characteristic by changing the input/output characteristics of the CMOS circuit 10. The resistor R1 is inserted and connected between the source of the p-channel MOS transistor MP1 and the power supply Vdd. The resistor R2 is inserted and connected between the source of the n-channel MOS transistor MN1 and ground GND1. The resistors R1, R2 have equal resistance values. Further, the resistors R1, R2 do not affect the input/output characteristics of the CMOS circuit 10. However, by shorting either one of the resistors R1, R2, the threshold voltage can be changed for generating a desired hysteresis characteristic.

The p-channel MOS transistor MP3 and the n-channel MOS transistor MN3 are switching devices for controlling the shorting and opening of corresponding resistors R1 and R2. Accordingly, the p-channel MOS transistor MP3, which is connected in parallel with the resistor R1, has its source connected to a power supply Vdd1 and its drain connected to the source of the p-channel MOS transistor MP1. The p-channel MOS transistor MP3 is configured to short the resistor R1 when the p-channel MOS transistor MP3 is switched on and configured to open the resistor R1 (conduction state) when the p-channel MOS transistor MP3 is switched off. Likewise, the n-channel MOS transistor MN3, which is connected in parallel with the resistor R2, has its source connected to ground GND1 and its drain connected to the source of the n-channel MOS transistor MN1. The n-channel MOS transistor MN3 is configured to short the resistor R2 when the n-channel MOS transistor MN3 is switched on and configured to open the resistor R2 when the n-channel MOS transistor MN3 is switched off.

Since either one of the MOS transistors (switching devices) MP3, MN3 is switched on according to the level of the input signal, only one of the total resistance value of the p-channel MOS transistor MP3 and the resistor R1 and the total resistance value of the n-channel MOS transistor MN3 and the resistor R2 is controlled to become small according to the corresponding one of the MOS transistors (switching devices) MP3, MN3 that is switched on.

The gate of the p-channel MOS transistor MP3 and the gate of the n-channel MOS transistor MN3 are connected to each other and commonly connected to an output part Y1 of the second CMOS circuit (switching control circuit) 20. Therefore, the switching on and off of the p-channel MOS transistor MP3 and the n-channel MOS transistor MN3 is controlled by the output of the switching control circuit 20. In other words, in a case where an L level voltage is output from the output part Y1 of the switching control circuit 20, the p-channel MOS transistor MP3 is switched on to short the resistor R1 whereas the n-channel MOS transistor MN3 is switched on to short the resistor R2 in a case where an H level voltage signal is output from the output part Y1 of the switching control circuit 20.

From the switching operation described above, it can be understood that the p-channel MOS transistor MP3 and the n-channel MOS transistor MN3 operate to complement one another. Thus, the p-channel MOS transistor MP3 and the n-channel MOS transistor MN3 are also configured to serve as a CMOS circuit.

The switching control circuit 20, which is configured as a CMOS circuit including the p-channel MOS transistor MP2 and the n-channel MOS transistor MN2, controls the p-channel MOS transistor MP3 and the n-channel MOS transistor MN3 (switching devices) according to the signal output from the output part Y of the CMOS circuit 10.

The gate of the p-channel MOS MP2 and the gate of the n-channel MOS transistor MN2 are commonly connected to the output part Y of the CMOS circuit 10 to form an input part A1. Further, the drain of the p-channel MOS MP2 and the drain of the n-channel MOS transistor MN2 are connected to form the output part Y1. The source of the p-channel MOS transistor MP2 is connected to a power supply Vdd2. The source of the n-channel MOS transistor MN2 is connected to ground GND2. The switching on and off of the p-channel MOS transistor MP3 and the n-channel MOS transistor MN3 which serve as switching devices are controlled by the output part Y1.

Because a signal input to the input part A of the CMOS circuit 10 is inverted and output at the output part Y and then further inverted and output at the output part Y1 of the switching control circuit 20, the voltage input to the switching devices MP3, MN3 has substantially the same phase as that of the voltage input to the input part A of the CMOS circuit 10. In other words, the switching control circuit 20 controls the switching devices MP3, MN3 so that positive feedback is achieved. Hence, with the CMOS inverter circuit 100 according to the first embodiment of the present invention, switching devices MP3, MN3 are controlled to achieve positive feedback by generating signals having the same phase as that of the voltage input to the CMOS circuit 10.

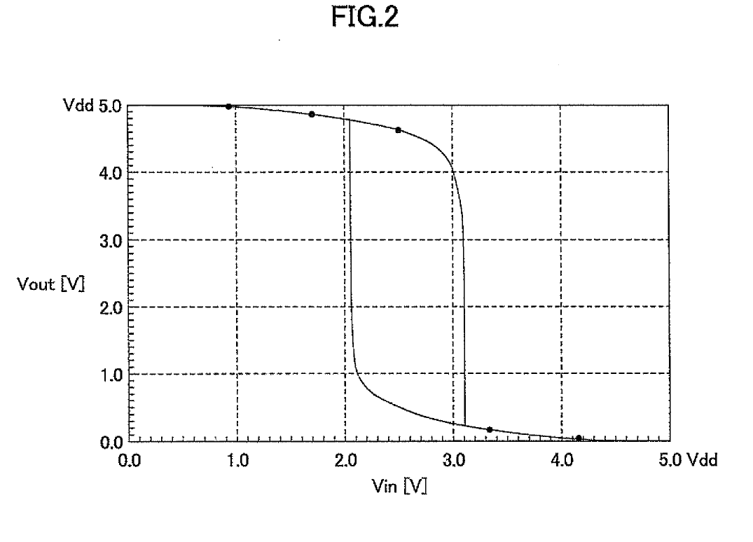

Next, an operation of the CMOS inverter circuit 100 illustrated in FIG. 1 is described with reference to FIGS. 1 and 2. FIG. 2 is a graph for illustrating input/output characteristics of the CMOS inverter circuit (NOT gate) 100 according to the first embodiment of FIG. 1.

In FIG. 2, the horizontal axis is for indicating input voltage Vin [V] input to the input part A and the vertical axis is for indicating output voltage Vout [V] output from the output part Y. It is to be noted that the input part A of the CMOS circuit 10 corresponds to the input of the entire CMOS inverter circuit (NOT gate) 100 and the output part Y of the CMOS circuit 10 corresponds to the output of the entire CMOS inverter circuit (NOT gate) 100 according to the first embodiment of the present invention.

In FIG. 2, the output voltage Vout is an H level in a case where the input voltage Vin is sufficiently low (i.e. where the input voltage Vin is apparently an L level). According to the circuit diagram of FIG. 1, an H level signal is output from the output part Y when an L level signal is input to the input part A of the CMOS circuit 10. Then, an L level signal is output from the output part Y1 of the switching control part 20 when an H level signal is input to the input part A1 of the switching control part 20. Thereby, the p-channel MOS transistor (switching device) MP3 is switched on and causes the resistor R1 to be in a shorted state. Thus, in a case where the resistor R1 is shorted and the resistor R2 is open, the resistance on the p-channel MOS transistor MP1 side is less than the resistance on the n-channel MOS transistor MN1 side. Accordingly, the input/output characteristic curve of FIG. 2 shifts towards the power supply voltage Vdd (towards the right side in FIG. 2).

On the other hand, the output voltage Vout is an L level in a case where the input voltage Vin is sufficiently high (i.e. where the input voltage Vin is apparently an H level). According to the circuit diagram of FIG. 1, an L level signal is output from the output part Y when an H level signal is input to the input part A of the CMOS circuit 10.

Then, an H level signal is output from the output part Y1 of the switching control part 20 when an L level signal is input to the input part A1 of the switching control part 20. Thereby, the n-channel MOS transistor (switching device) MN3 is switched on and causes the resistor R2 to be in a shorted state. Thus, in a case where the resistor R2 is shorted and the resistor R1 is open, the resistance on the n-channel MOS transistor MN1 side is less than the resistance on the p-channel MOS transistor MP1 side. Accordingly, the input/output characteristic curve of FIG. 2 shifts toward ground voltage GND (toward the left side in FIG. 2).

As described above, the switching of switching devices MP3, MN3 is performed to supply voltage having the same phase as the input voltage Vin for generating positive feedback by connecting the p-channel MOS transistor MP1 and the n-channel MOS transistor MN1 of the CMOS circuit 10 in series with the respective resistors R1, R2 and connecting the switching devices MP3, MN3 in parallel with the respective resistors R1, R2. Thereby, a NOT gate having a desired hysteresis characteristic can be obtained with a simple circuit using the resistors R1 and R2. Accordingly, a NOT gate with little chattering can be attained. Because the hysteresis characteristic of the CMOS inverter circuit 100 can easily be adjusted by adjusting the resistance values of the resistors R1, R2, the CMOS inverter circuit 100 serves as a logic circuit that can easily be adjusted according to purpose.

### Second Embodiment

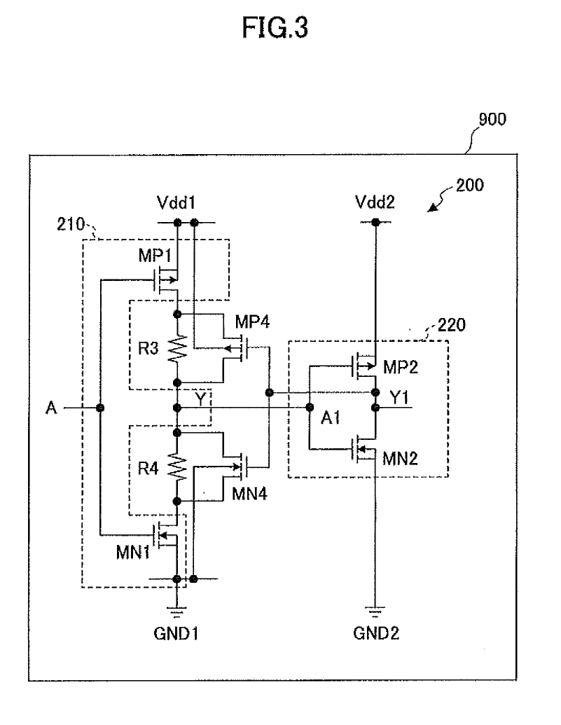

FIG. 3 illustrates a CMOS inverter circuit 200 according to the second embodiment of the present invention. In FIG. 3, the CMOS inverter circuit (NOT gate) 200 according to the second embodiment has a first CMOS circuit 210 including a p-channel MOS transistor MP1 and an n-channel MOS transistor MN1; a resistor R3 connected in series with an output part Y of the CMOS circuit 210 and the drain of the p-channel MOS transistor MP1; a resistor R4 connected in series with the output part Y and the n-channel MOS transistor MN1; a p-channel MOS transistor (switching device) MP4 connected in parallel with the resistor R3; an n-channel MOS transistor (switching device) MN4 connected in parallel with the resistor R4; and a second CMOS circuit (also referred to as “switching control circuit” described in detail below) 220 including a p-channel MOS transistor MP2 and an n-channel MOS transistor MN2. In the CMOS inverter circuit 200 of FIG. 3, like components are denoted by like numerals as of those of the CMOS inverter circuit 100 of the first embodiment.

The CMOS inverter circuit 200 according to the second embodiment of the present invention is different from the CMOS inverter circuit 100 of the first embodiment in that the CMOS inverter circuit 200 has the resistors R3, R4 connected between corresponding drains of the p and n channel MOS transistors MP1, MN1 and the output part Y whereas the CMOS inverter circuit 100 has the resistor R1 connected between the source of the p channel MOS transistor MP1 and the power supply Vdd and the resistor R2 connected between the source of the n-channel MOS transistor NIT and the ground GND1.

Thus, according to the CMOS inverter circuit 200 of the second embodiment, the resistors R3, R4 serving to adjust the threshold voltage of the CMOS inverter circuit 200 may be provided toward the drain side of the p and n channel MOS transistors MP1, MN1 of the CMOS circuit 10. Because the resistors R3, R4 have a function of dividing and adjusting the voltage of the p-channel MOS transistor MP1 and the n-channel. MOS transistor MN1, the resistors R3, R4 may be connected to either the source side or the drain side of the p and n channel MOS transistors MP1, MN1 on condition that the resistors R3, R4 are connected to the p and n channel MOS transistors MP1, MN1 under the same conditions.

The functions of the p-channel MOS transistor (switching device) MP4 for switching between a shorted state and an open state of the resistor R3 and the n-channel MOS transistor (switching device) MN4 for switching between a shorted state and an open state of the resistor R4 do not change even where the positions of the resistors R3, R4 are moved to the respective drain sides of the p and n channel MOS transistors MP1, MN1. In other words, the p-channel MOS transistor MP4 and the n-channel MOS transistor MN4 are switched on and off for attaining the same phase as that of the CMOS circuit 210 based on control signals output from the output part Y1 of the switching control circuit 20, so that the p-channel MOS transistor MP4 is switched on and the resistor R3 shorted when an L level signal is input to the input part A and the n-channel MOS transistor MN4 is switched on and the resistor R4 shorted when an H level signal is input to the input part A.

Other than the differences described above, the CMOS circuit 210 and the switching control circuit 220 operate in the same manner as the CMOS circuit 10 and the switching control circuit 20. Thus, components such as the MOS transistors MP1, MN1, MP2, MN2 are not further described.

With the CMOS inverter circuit according to the second embodiment of the present invention, a NOT gate having a desired hysteresis characteristic (e.g., hysteresis characteristic illustrated in FIG. 2) can be obtained with a simple circuit using the resistors R3 and R4. Accordingly, a NOT gate with little chattering can be attained. Further, the hysteresis characteristic of the CMOS inverter circuit 200 can easily be adjusted by adjusting the resistance value of the resistors R3, R4.

### Third Embodiment

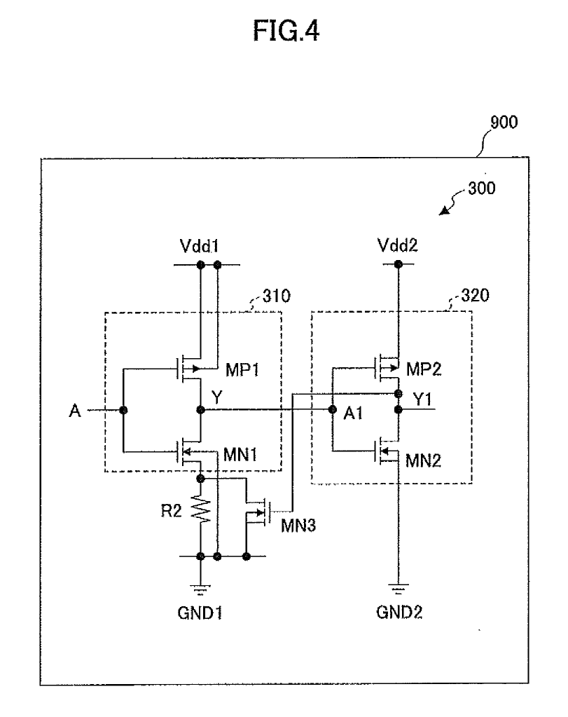

FIG. 4 illustrates a CMOS inverter circuit 300 according to the third embodiment of the present invention. In FIG. 4, the CMOS inverter circuit 300 according to the third embodiment has a first CMOS circuit 310 including a p-channel MOS transistor MP1 and an n-channel MOS transistor MN1; a resistor R2 connected in series with the source of the n-channel MOS transistor MN1 and ground GND1; an n-channel MOS transistor (switching device) MN3 having its drain and source connected in parallel with the resistor R2; and a second CMOS circuit (also referred to as “switching control circuit” described in detail below) 320 including a p-channel MOS transistor MP2 and an n-channel MOS transistor MN2. In the CMOS inverter circuit 300 of FIG. 4, like components are denoted by like numerals as of those of the CMOS inverter circuit 100 of the first embodiment.

The CMOS inverter circuit 300 according to the third embodiment of the present invention is different from the CMOS inverter circuit 100 of the first embodiment in that the CMOS inverter circuit 300 only has the resistor R2 connected to the source of the n-channel MOS transistor MN1 and has no resistor connected to the p-channel MOS transistor MP1. Because of this configuration, the n-channel MOS transistor (switching device) MN3 for controlling the shorting and opening of the resistor R2 is connected in parallel with the resistor R2 between the source of the n-channel MOS transistor MN1 and ground GND1.

Thus, according to the CMOS inverter circuit 300 of the third embodiment, the resistor R2 and the switching device MN3 may be provided only on one side of the p and n channel MOS transistors MP1, MN1 of the CMOS circuit 310 instead of providing resistors and switching devices on both sides of a CMOS circuit.

As described above, the configuration of FIG. 4 has the resistor R2 connected between the source of the n-channel MOS transistor MN1 and ground GND1 and the switching device MN3 connected in parallel with the resistor R2. Accordingly, the input/output characteristic of the CMOS inverter circuit 300 according to the third embodiment of the present invention exhibits no hysteresis when the signal voltage output from the output part Y switches from a high level to a low level in a case where the signal voltage input to the input part A is switched from a low level to a high level. However, when the signal voltage output from the output part Y switches from a low level to a high level in a case where the signal voltage input to the input part A is switched from a high level to a low level, the input/output characteristic of the CMOS inverter circuit 300 according to the third embodiment of the present invention exhibits a hysteresis characteristic. In other words, the input/output characteristic of the CMOS inverter circuit 300 according to the third embodiment of the present invention exhibits a characteristic corresponding only to the characteristic curve that shifts toward zero potential when the output voltage Vout switches from a low level to a high level where the signal voltage input to the input part A is switched from a high level to a low level.

Alternatively, by providing a resistor and a switching device only between the source of the p-channel MOS transistor MP1 and the power supply Vdd, the input/output characteristic of the CMOS inverter circuit 300 according to the third embodiment of the present invention can exhibit a characteristic corresponding only to the characteristic curve that shifts toward the power supply voltage Vdd when the output voltage Vout switches from a high level to a low level where the signal voltage input to the input part A is switched from a low level to a high level. Thus, a NOT gate having a hysteresis characteristic, which shifts only toward a single direction, can be obtained.

Other than the differences described above, the CMOS circuit 310 and the switching control circuit 320 operate in the same manner as the CMOS circuit 10 and the switching control circuit 20. Thus, components such as the MOS transistors MP1, MN1, MP2, MN2 are not further described.

With the CMOS inverter circuit according to the third embodiment of the present invention, a NOT gate exhibits a hysteresis characteristic only when switching occurs in a single direction. Accordingly, a NOT gate with little chattering can be attained. Further, the hysteresis characteristic of the CMOS inverter circuit 300 can easily be adjusted by adjusting the resistance value of the resistor R2.

### Fourth Embodiment

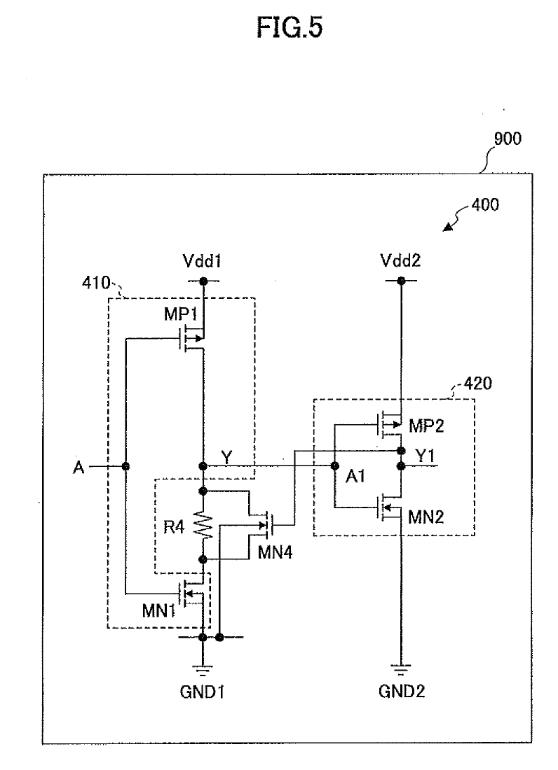

FIG. 5 illustrates a CMOS inverter circuit 400 according to the fourth embodiment of the present invention. The same as the CMOS inverter circuits 100, 200, 300 of the first-third embodiments of the present invention, the CMOS inverter circuit 400 according to the fourth embodiment also has a first CMOS circuit 410 including a p-channel MOS transistor MP1 and an n-channel MOS transistor MN1 and a second CMOS circuit (also referred to as “switching control circuit” described in detail below) 420 including a p-channel MOS transistor MP2 and an n-channel MOBS transistor MN2 as shown in FIG. 5. However, the CMOS inverter circuit 400 of the fourth embodiment is different from the CMOS inverter circuits 100, 200, 300 of the first-third embodiments in that only a single resistor R4 and a single n-channel MOS transistor (switching device) MN4 connected in parallel with the resistor R4 are provided between the drain of the n-channel MOS transistor MN1 and an output part Y.

Thus, according to the CMOS inverter circuit 400 of the fourth embodiment, a resistor and a switching device may be provided only on one side of the drains of the p-channel MOS transistor MP1 and the n-channel MOS transistor MN1 of the CMOS circuit 410. In the fourth embodiment shown in FIG. 5, the resistor R4 and the switching device MN4 are provided only between the drain of the n-channel MOS transistor MN1 and the output part Y.

The same as the third embodiment, the configuration of the fourth embodiment has an input/output characteristic that shifts toward zero potential (ground) and exhibits a hysteresis characteristic when the output voltage Vout switches from a low level to a high level where the input voltage Vin is switched from a high level to a low level.

Alternatively, the same as the third embodiment, by providing a resistor and a switching device only between the drain of the p-channel MOS transistor MP1 and the output part Y, the input/output characteristic of the CMOS inverter circuit 400 according to the fourth embodiment of the present invention can exhibit a characteristic corresponding only to the characteristic curve that shifts toward the power supply voltage Vdd when the output voltage Vout switches from a high level to a low level whereas no hysteresis is exhibited when the output voltage Vout switches from a low level to a high level.

Other than the differences described above, the CMOS circuit 410 and the switching control circuit 420 operate in the same manner as the CMOS circuit 10 and the switching control circuit 20.

Thus, components such as the MOS transistors MP1, MN1, MP2, MN2 are not further described.

With the CMOS inverter circuit according to the fourth embodiment of the present invention, by providing the resistor R4 and the switching device MN4 only on one side of the drains of the p-channel MOS transistor MP1 and the n-channel MOS transistor MN1 of the CMOS circuit 410, a NOT gate exhibiting a hysteresis characteristic only when switching occurs in a single direction can be obtained. Accordingly, a NOT gate with little chattering can be attained. Further, the hysteresis characteristic of the CMOS inverter circuit 400 can easily be adjusted by adjusting the resistance value of the resistor R4.

In the first-fourth embodiment of the present invention, the resistors R1, R2, R3, and R4 are described as being connected in series with the p-channel MOS transistor MP1 and/or the n-channel MOS transistor MN1. Alternatively, MOS transistors may be used instead of the resistors R1, R2, R3, and R4, so that the on-resistances of the MOS transistors are used to configure a CMOS inverter circuit. Accordingly, because the resistors R1, R2, R3, and R4 are not limited to resistors but may be other resistance devices having a resistance components a NOT gate having a hysteresis characteristic can be obtained by using the on-resistances of the MOS transistors.

### Fifth Embodiment

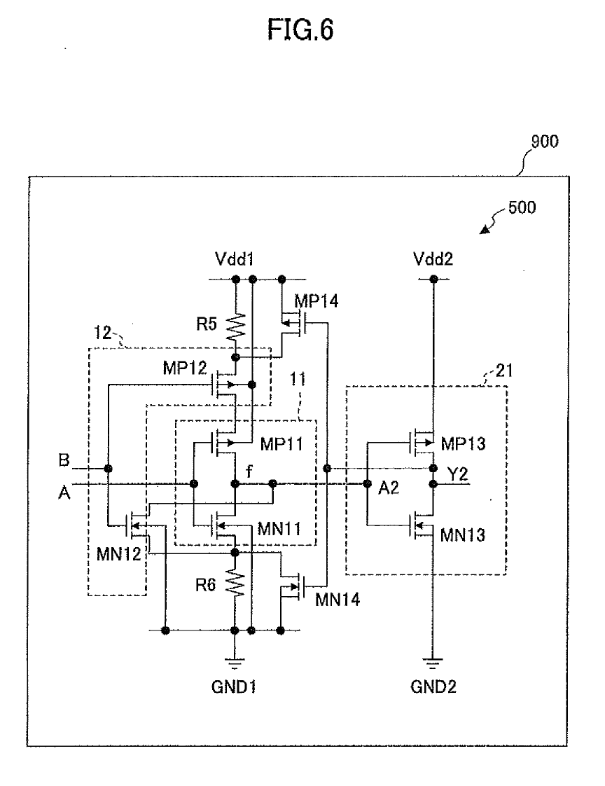

FIG. 6 illustrates a circuit configuration of a logic gate according to the fifth embodiment of the present invention. The logic gate of the fifth embodiment is configured as a NOR gate 500. As shown in FIG. 6, the NOR gate 500 has a first CMOS circuit 11 including a p-channel MOS transistor MP11 and an n-channel MOS transistor MN11; a second CMOS circuit 12 including a p-channel MOS transistor MP12 and an n-channel MOS transistor MN12; resistors R5, R6; switching devices MP14, MN14; and a switching control circuit 21 including a p-channel MOS transistor MP13 and an n-channel MOS transistor MN13.

Because the NOR gate 500 of the fifth embodiment has a 2 input-1 output configuration, the NOR gate 500 includes input parts A, B and an output part f. In a case where the output of the output part f is expressed as f(A, B), the output part f outputs f(0, 0)=1, f(0, 1)=0, f(1, 0)=0, f(1, 1)=0 because the logic gate of this embodiment is a NOR gate. It is to be noted that “0” corresponds to a low level voltage signal and “1” corresponds to a high level voltage signal.

In a case where one or both input parts A and B become a high level, the NOR gate of the fifth embodiment connects (causes conduction in) both of or one of the n-channel MOS transistors MN11, MN12 connected in parallel with each other and disconnects both of or one of the p-channel MOS transistors MP11, MP12, to thereby provide a NOR function.

For example, in a case where a high level signal is input to the input part A, the n-channel MOS transistor MN11 is switched on, the output part f outputs a low level signal, and the low level signal is input to an input part A, of the switching control circuit 21. Because the switching control circuit 21 is also an inverter circuit, an inverted high level signal is output from the output part Y2, the n-channel MOS transistor (switching device) MN14 is switched on, and the resistor R6 is shorted. Likewise, in a case where a high level signal is input to the input part B, the n-channel MOS transistor MN12 is switched on and a low level signal is output from the output part f. Then, the switching element MN14 is switched on by the switching control circuit 21, to thereby short the resistor R6. Even in a case where a high level signal is input to both the input part A and the input part B, the resistor R6 is shorted because a low level signal is output from the output part f. Accordingly, the NOR gate 500 of the fifth embodiment exhibits an input/output characteristic having a hysteresis characteristic.

On the other hand, in a case where a low level signal is input to both the input part A and the input part B, both the p-channel MOS transistor MP11 of the CMOS circuit 11 and the p-channel MOS transistor MP12 become on and a high level signal is output from the output part t. Then, a high level signal is input to the input part A2 of the switching control circuit 21, a low level signal is output from the output part Y2, and the p-channel MOS transistor (switching device) MP14 is switched off. Thereby, the resistor Rb is shorted. Accordingly, the NOR gate 500 of the fifth embodiment exhibits an input/output characteristic having a hysteresis characteristic.

Thus, a hysteresis characteristic can be attained even with a NOR gate by connecting resistors R5, R6 in series with the MOS transistors MP11, MP12, MN11, MN12 of the CMOS circuits 11, 12, connecting the switching devices MP14, MN14 in parallel with the resistors R5, R6, and controlling the switching devices MP14, MN14. Accordingly, a NOR gate with little chattering can be attained. Further, the hysteresis characteristic of the NOR gate 500 can easily be adjusted by adjusting the resistance value of the resistors R5 and R6.

### Sixth Embodiment

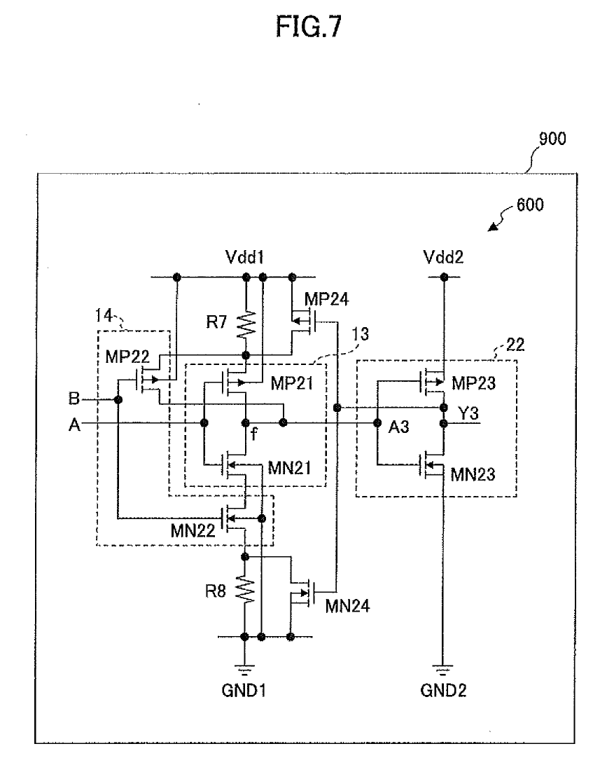

FIG. 7 illustrates a circuit configuration of a logic gate according to the sixth embodiment of the present invention. The logic gate of the sixth embodiment is configured as a NAND gate 600. As shown in FIG. 7, the NAND gate 600 has a first CMOS circuit 13 including a p-channel MOS transistor MP21 and an n-channel MOS transistor MN21; a second CMOS circuit 14 including a p-channel MOS transistor MP22 and an n-channel MOS transistor MN22; resistors R7, R8; a switching devices MP24, MN24; and a switching control circuit 22 including a p-channel MOS transistor MP23 and an a-channel MOS transistor MN23.

Because the NAND gate 600 of the sixth embodiment has a 2 input-1 output configuration, the NAND gate 600 includes input parts A, B and an output part f. In a case where the output of the output part f is expressed as f(A, B), the output part f outputs f(0, 0)=1, f(0, 1)=1, f(1, 0)=1, f(1, 1)=0 because the logic gate of this embodiment is a NAND gate. It is to be noted that “0” corresponds to a low level voltage signal and “1” corresponds to a high level voltage signal.

The NAND gate 600 of the sixth embodiment has the p-channel MOS transistors MP21, MP22 of the CMOS circuits 13, 14 connected in parallel with a power supply Vdd1 and the n-channel MOS transistors MN21, MN22 of the CMOS circuits 11, 12 connected in series with ground GND1. Therefore, the NAND gate 600 of the sixth embodiment provides a NAND gate function in which a high level signal is output from the output part f when a low level signal is input to both or one of the input parts A and B whereas a low level signal is output from the output part f only when high level signals are input to both the input parts A and B.

For example, in a case where a low level signal is input to the input part A, the p-channel MOS transistor MP21 is switched on and the output part f outputs a high level signal. Thereby, the switching control circuit 22 has the high level signal input to its input part A3 and a low level signal output from its output part Y3. Accordingly, the p-channel MOS transistor (switching device) MP24 is switched on and the resistor R7 is shorted. Likewise, in a case where a low level signal is input to the input part B, the p-channel MOS transistor MP22 is switched on and the output part f outputs a high level signal. Thereby, the switching control circuit 22 inverts the high level signal to a low level signal and outputs the low level signal from its output part Y3. Accordingly, the p-channel MOS transistor (switching device) MP24 is switched on and the resistor R7 is shorted. The results of switching on the p-channel MOS transistor (switching device) MP24 on and shorting the resistor R7 are also obtained in a case where a low level signal is input to both the input part A and the input part B.

On the other hand, in a case where a high level signal is input to both the input part A and the input part Br both the n-channel MOS transistors MN21, MN22 connected in series with the ground GND1 are switched on. Therefore, a low level signal is output from the output part f. When the low level signal is input to the input part A3 of the switching control circuit 22, the p-channel MOS transistor MP23 is switched on and a high level signal is output from the output part Y3. Accordingly, the n-channel MOS transistor (switching device) MN24 is switched on and the resistor R8 is shorted.

Thus, in accordance with the combination of signals input to the input parts A and B, only the resistor R8 being connected to ground GND1 is shorted when the output voltage Vout of the output part f is a low level whereas only the resistor R7 being connected to the power supply Vdd1 is shorted when the output voltage Vout of the output part f is a high level. Therefore, a hysteresis characteristic can be attained even with a NAND gate. Accordingly, a NAND gate with little chattering can be attained. Further, the hysteresis characteristic of the NAND gate 600 can easily be adjusted by adjusting the resistance value of the resistors R7 and R8.

The resistors R5, R6, R7, and R8 in the fifth and sixth embodiments of the present invention are not limited to resistors but may be other resistance devices having a resistance component (e.g., MOS transistor). For example, the on-resistance of a MOS transistor can be used for serving as a resistance.

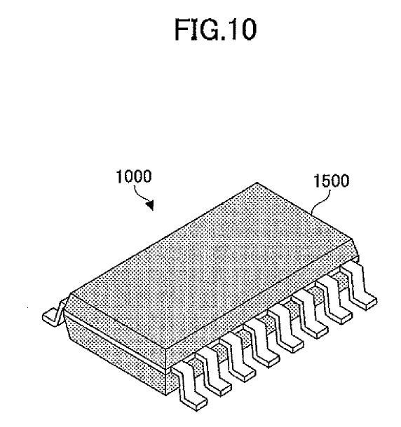

Furthermore, an OR gate having a hysteresis characteristic can be obtained by combining the NOR gate of the fifth embodiment with one of the NOT gates of the first-fourth embodiments. Furthermore, an AND gate having a hysteresis characteristic can be obtained by combining the NAND gate of the sixth embodiment with one of the NOT gates of the first-fourth embodiments. By using these combinations of logic gates, a desired logic circuit can be obtained. For example, a desired logic circuit can be formed in a semiconductor substrate 900 using the logic gates 100-600 of the first-sixth embodiments of the present invention. For example, by installing (i.e. packaging) the semiconductor substrate 900 including the logic gate(s) 100-600 in a package 1500 as shown in FIG. 10, a semiconductor integrated circuit device 1000 having a desired logic circuit can be obtained. That is, the logic gates according to the embodiments of the present invention can be suitably used in logic integrated circuit (IC) devices.

Further, the present invention is not limited to these embodiments, but variations and modifications may be made without departing from the scope of the present invention.

The present application is based on Japanese Priority Application No 2007-278065 filed on Oct. 25, 2007, with the Japanese Patent Office, the entire contents of which are hereby incorporated by reference.

What is claimed is:

1. A logic gate including a CMOS circuit having a p-channel MOS transistor and an n-channel MOS transistor, comprising:
a resistance device connected in series with a source or a drain of at least one of the p-channel MOS transistor and the n-channel MOS transistor;
a switching device connected in parallel with the resistance device and configured to switch the resistance device on and off; and
a switching control circuit configured to control the switching on and off of the switching device according to an output signal output from the CMOS circuit.

2. The logic gate as claimed in claim 1, wherein the switching control circuit is configured to control the switching on and off of the switching device by using a signal having the same phase as an input signal input to the CMOS circuit.

3. The logic gate as claimed in claim 1, wherein the resistance device is a resistor.

4. The logic gate as claimed in claim 1, wherein the resistance device is a MOS transistor.

5. The logic gate as claimed in claim 1, wherein the logic gate is a NOT gate.

6. The logic gate as claimed in claim 1, wherein the logic gate is a NOR gate.

7. The logic gate as claimed in claim 1, wherein the logic gate is a NAND gate.

8. A semiconductor integrated circuit device comprising:
a semiconductor substrate having a logic gate including a CMOS circuit having a p-channel MOS transistor and an n-channel MOS transistor, the logic gate including
a resistance device connected in series with a source or a drain of at least one of the p-channel MOS transistor and the n-channel MOS transistor,
a switching device connected in parallel with the resistance device and configured to switch the resistance device on and off, and
a switching control circuit configured to control the switching on and off of the switching device according to an output signal output from the CMOS circuit; and
a package having the semiconductor substrate installed therein.
